(19) United States
(12) Patent Application Publication
(10) Pub. No.: US 2012/0132278 A1
(43) Pub. Date: May 31, 2012

(54) LUMINESCENT SOLAR ENERGY CONCENTRATOR

(75) Inventors: Roland Winston, Chicago, IL (US); David G. Pelka, Los Angeles, CA (US)

(73) Assignee: The Regents of the University of California

(21) Appl. No.: 13/193,010

(22) Filed: Jul. 28, 2011

Related U.S. Application Data
(60) Provisional application No. 61/369,293, filed on Jul. 30, 2010.

(51) Int. Cl. H01L 31/0232; G02B 6/00

(52) U.S. Cl. 136/257; 136/259; 385/141

(57) ABSTRACT

An apparatus is disclosed including a wave-guide containing a luminescent material which responds to incident light by emitting frequency-shifted light. A first portion of the frequency-shifted light is internally reflected within the wave-guide to a wave-guide output, and a second portion of the frequency-shifted light is transmitted out of the wave-guide. The apparatus further includes a diffuse reflector positioned proximal to the waveguide to reflect at least some of the second portion of the frequency-shifted light hack in to the waveguide to be internally reflected within the wave-guide to a wave-guide output.

### CROSS-REFERENCE TO RELATED APPLICATION

This application claims priority under 35 U.S.C. §1.19(e) to U.S. Provisional Application No, 61/369,293, filed Jul. 30, 2010, the contents of which is incorporated by reference into the present application.

### BACKGROUND

This disclosure relates to the concentration of light, and, more particularly, the concentration of light using an optical element.

Typically, light concentrators are designed to receive light incident over a range of angles less than an acceptance angle at an aperture. The light is concentrated onto a region (e.g., on an absorber) with an area smaller than the area of the aperture. The ratio of the aperture area to the smaller area is known as the geometric concentration. The laws of thermodynamics set a theoretical upper bound, known in the art as the “thermodynamic limit,” to the concentration for a given concentrator configuration. Many types of solar concentrators have been studied including reflective and refractive devices. Concentrators may be imaging or non imaging, and may be designed to correct for various types of optical aberration (spherical aberration, coma, astigmatism, chromatic aberration, etc.).

Optical concentrators may be applied, for example, in the conversion of solar energy to electricity (or other form of energy). The power that a photovoltaic solar cell can produce is a function of the incident sunlight. A typical solar cell can utilize efficiently many times the un-concentrated incident sunlight in typical settings, provided that the temperature of the solar cell does not increase excessively. Therefore, an optical concentrator can be employed to concentrate sunlight onto a photovoltaic cell to improve the output of the photovoltaic cell. The output will increase with the concentration factor. At appreciable concentration factors, cooling may be required, since the efficiency of some photovoltaic cells may decrease rapidly with increasing temperatures.

To effectively capture more of the available sunlight, concentrators and or the solar cells may be configured to move over the course of the day to follow or track the position of the sun as it changes over the course of the day and over the course of the year. Such tracking systems may move along a single axis or multiple axes and may be either passive systems or active systems that use electrical motors or other powered devices to move the solar energy system. Tracking systems add an additional source of complexity and cost to a solar energy system.

Silicon accounts for the vast majority of photovoltaic and solar cell devices currently in use. Si-based devices are relatively low cost, easy to fabricate, and may be made from abundantly available materials. Accordingly, Si-based devices are a good candidate for use in solar power generation, where power generation cost is often critical to the commercial feasibility of a device. However, Si-based solar devices do suffer from drawbacks. Notably, the devices face certain limitation in efficiency of performance. Typical Si-based devices have an average 23% efficiency factor for sunlight to electrical power conversion. A variety of solar cell designs (tandem cells, multi-junction cells, intermediate band gap cells, etc.) and photoactive materials used in place of or in conjunction with Si (including organic dyes, polymers and quantum dots), have been proposed, but increases in efficiency have been limited. The best efficiency achieved so far in typical operational devices has not exceeded ˜40%.

The reduced efficiency of silicon-based solar cells is due, in part, to a mismatch between the silicon band gap and the solar spectrum. Solar cells operate as quantum energy conversion devices, and are therefore subject to the “thermodynamic efficiency limit”. Photons with an energy below the band gap of the absorber material cannot generate a hole-electron pair, and so their energy is not converted to useful output and only generates heat if absorbed. For photons with energy above the band gap energy, only a fraction of the energy above the band gap can be converted to useful output. When a photon of greater energy is absorbed, the excess energy above the band gap is converted to kinetic energy of the carrier combination. The excess kinetic energy is converted to heat through phonon interactions as the kinetic energy of the carriers slows to equilibrium velocity.

Si has a band gap of about 1.12 eV, corresponding to near infrared radiations (i.e. at about 1100 nm). About 48% of the energy of the solar spectrum is in the infrared range (700-2500 nm), about 44% is in the visible range (400-700 nm) and 7% in the ultraviolet range (<400 μm). The efficiency of Si is therefore reduced at shorter wavelengths in the spectrum, i.e. the visible and ultraviolet side of the spectrum. Because of this, the external quantum efficiency (EQE) of Si is low where the solar spectrum flux is high.

### SUMMARY

The inventor has realized that it is advantageous to provide the devices and techniques described herein to improve the efficiency of power generation systems featuring photovoltaic devices, e.g. Si-based solar cell devices. In particular, the inclusion of a diffuse reflector which directs which directs light lost from a wave guide back into the wave guide at suitable angles to be guided to a wave-guide output can provide substantial improvements in efficiency. In addition the inclusion of a selective reflecting top layer which transmits a significant portion of the solar spectrum but reflects the frequency shifted (e.g., Stokes shifted) light may be advantageous in returning light to the wave guide which would otherwise be lost through the escape cone. There is preferably an air gap between the light guide and selective reflector so as not to frustrate total internal reflection. As is well known in the art, high efficiency is often important or even critical to the commercial viability of energy sources, particularly in the solar energy field. The devices and techniques described herein provide for relatively low cost devices useful for power generation with increased efficiency.

The inventor has further realized that the “thermodynamic limit to concentration” can be circumvented if light is absorbed and then emitted at a longer wave length (known as a Stokes shift) in an exothermic process that adds heat to the medium. This is because entropy (S) depends logarithmically on phase space but linearly on heat deposited in the environment (Q): S≈k log G+const, where k is Boltzmann's constant. Here, the optical counterpart, optical etendue (G) is substituted for “phase space,” which is technically correct up to factors of frequency ( [symbol] squared) which do not materially effect the conclusions. Because brightness (B) is power (P) divided by etendue (G),

$$log B \approx \frac{S}{k} + const ,$$

or, more accurately,

$$log \frac{B}{{v}^{2}} \approx \frac{S}{k} + const .$$

It follows that in a down shifting (Stokes shift) process: hv→hv′, ΔQ=h(v−v′),

$$k log {B}^{′} - k log B = \frac{Δ Q}{T} , and \frac{{B}^{′}}{B} = {( \frac{{v}^{′}}{v} )}^{2} {e}^{\frac{h ( v - {v}^{′} )}{kT}} ;$$

where h is Planck's constant, u and u′ are the wavelengths of light before and after the Stokes shift, respectively, and T is temperature. The potentially huge exponential is because kT is approximately 0.025 eV (electronvolts) for room temperature, while the Stokes shift is typically ˜0.5 eV.

In a stationary optical system which accepts the entire hemisphere, the etendue is [symbol] and

$$B \approx \frac{P}{π \times area} ,$$

so there is no further opportunity to increase

$$\frac{P}{area}$$

(e.g., to concentrate the radiation). The conventional statement is: diffuse radiation cannot be concentrated. However, the Stokes shift process does allow concentration of diffuse radiation, and that is the basis of the luminescent concentrators.

One embodiment relates to an apparatus including a wave-guide containing a luminescent material which responds to incident light by emitting frequency-shifted light. A first portion of the frequency-shifted light is internally reflected within the wave-guide to a wave-guide output, and a second portion of the frequency-shifted light is transmitted out of the wave-guide. The apparatus further includes a diffuse reflector positioned proximal to the waveguide to reflect at least some of the second portion of the frequency-shifted light back in to the waveguide to be internally reflected within the wave-guide to a wave-guide output. There is preferably an air gap between the light guide and diffuse reflector so as not to frustrate total internal reflection.

In some embodiments, the apparatus includes an absorber positioned proximal to the wave-guide to produce energy in response to the frequency-shifted light.

In some embodiments, the apparatus includes an absorber that is a photovoltaic device.

In some embodiments, the diffuse reflector reflects greater than about 90% of the frequency shifted light incident upon it.

In some embodiments, the luminescent material may be quantum dots or an organic dye.

In some embodiments, the quantum dots comprise particles ranging between about 1 to 10 nanometers in size.

In some embodiments, the quantum dots includes material is selected from the group consisting of lead sulfide (PbS), cadmium selenide (CdSe), cadmium sulfide (CdS), indium arsenide (InAs), and indium phosphide (InP).

In some embodiments, the quantum dots include material selected from the group consisting of zinc selenide (ZnSe), and titanium dioxide (TiO2).

In some embodiments, the layer of quantum dots includes a monolayer of quantum dots.

In some embodiments, the apparatus the quantum dots are suspended in a polymeric material.

In some embodiments, the apparatus the waveguide includes an upper layer which is substantially transparent to the incident light; an active layer comprising the luminescent material, the active layer underlying the upper layer; and a lower layer underlying the active layer which is substantially transparent to the frequency-shifted light. The diffuse reflector includes a diffusely reflective layer underlying the lower layer.

In some embodiments, the apparatus further includes a selectively reflective layer overlying the upper layer which is substantially transparent to the incident light and selectively reflects the frequency-shifted light.

In some embodiments, the incident light is solar light.

In some the frequency-shifted light is red shifted relative to the solar light.

In some embodiments, at least portions of the selectively reflective later and the diffusely reflective layer face each other to form a reflective cavity for the frequency-shifted light.

In some embodiments, the apparatus further includes a selective reflector located proximal the waveguide which selectively admits the incident light into the waveguide and which selectively reflects frequency-shifted light from the wave-guide back into the waveguide.

In some embodiments, at least portions of the selective reflector and the diffuse reflector face each other to form a reflective cavity for the frequency-shifted light.

In some embodiments, the selective reflector has a transmissivity of at least 0.9 to incident light and a reflectivity of at least 0.9 to the red shifted light.

In some embodiments, the waveguide is flexible.

In some embodiments, the waveguide includes a fluid filled shell.

In some embodiments, the apparatus further includes a circulator which circulates fluid through the fluid filled shell.

In some embodiments, the apparatus further includes a heat exchanger configured to remove heat from the fluid.

In some embodiments, the apparatus further includes at lease one heat sink configured to remove heat from the waveguide.

In some embodiments, the apparatus further includes a generator configured to generate electrical power from the removed heat.

In some embodiments, the apparatus further includes a concentrator which concentrates the incident light onto the waveguide.

Another embodiment relates to a method of generating electrical power. The method includes obtaining a concentrating apparatus comprising a wave-guide containing a luminescent material which responds to incident light by emitting frequency-shifted light and a diffuse reflector positioned proximal to the waveguide. A first portion of the frequency-shifted light is internally reflected within the wave-guide to a wave-guide output, and a second portion of the frequency-shifted light is transmitted out of the wave-guide. The diffuse reflector reflects at least some of the second portion of the frequency-shifted light back in to the waveguide to be internally reflected within the wave-guide to a wave-guide output. The method also includes positioning a photovoltaic device proximal to the wave-guide output; receiving incident light with the concentrating apparatus to produce frequency-shifted light; and directing at least a portion of the frequency-shifted light to the photovoltaic device to generate electrical power.

In some embodiments, the method includes admitting a portion of the incident light into the waveguide through the selective reflective surface and onto the luminescent material; causing the luminescent material to emit frequency-shifted light in response to the incident light; and using the diffuse reflector to reflect a portion of the frequency-shifted light which exits the waveguide back into the waveguide to be internally reflected within the wave-guide to the wave-guide output.

In some embodiments, the incident light is solar light.

In some embodiments, the frequency-shifted light is red shifted relative to the solar light.

In some embodiments, the luminescent material includes quantum dots.

in some embodiments, the quantum dots comprise particles ranging between about 2 to 10 nanometers in size.

In some embodiments, the quantum dots include material selected from the group consisting of cadmium selenide (CdSe), cadmium sulfide (CdS), indium arsenide (InAs), and indium phosphide (InP).

In some embodiments, the quantum dots include material selected from the group consisting of lead sulfide (PbS), zinc selenide (ZnSe), and titanium dioxide (TiO2).

In some embodiments, the concentration apparatus further includes a selective reflector located proximal the waveguide which selectively admits the incident light into the waveguide and which selectively reflects frequency-shifted light from the wave-guide back into the waveguide. The method further includes admitting a portion of the incident light into the waveguide through the selective reflective surface and onto the luminescent material; causing the luminescent material to emit frequency-shifted light in response to the incident light; and using the selective reflector to reflect a portion of the frequency-shifted light which exits the waveguide back into the waveguide to be internally reflected within the wave-guide to the wave-guide output.

In some embodiments, the selective reflector is a diffuse reflector.

Still another embodiment relates to a system including an apparatus with a wave-guide containing a luminescent material which responds to incident light by emitting frequency-shifted light and an energy transducer located proximal to the wave guide output to receive frequency shifted light and convert the light to another form of energy.

In some embodiments, the transducer includes a photovoltaic cell.

In some embodiments, the photovoltaic cell has a higher quantum efficiency in response to the frequency shifted light than in response to the incident light.

In some embodiments, the photovoltaic cell includes a silicon based solar cell.

Yet another embodiment relates to an apparatus including a wave-guide and a diffuse reflector. The wave-guide contains a luminescent material which responds to incident light by emitting frequency-shifted light. The diffuse reflector is positioned proximal to the waveguide to reflect at least some light exiting the waveguide back in to the waveguide to be internally reflected within the wave-guide.

In some embodiments, the at least some light exiting the waveguide includes frequency-shifted light emitted from the luminescent material.

in some embodiments, the at least some light exiting the waveguide includes a non-frequency-shifted portion of the incident light.

Various embodiments may include any of the features described herein, either alone, or in any suitable combination.

It is to be understood that both the foregoing general description and the following detailed description are exemplary and explanatory only, and are not restrictive of the invention as claimed.

### BRIEF DESCRIPTION OF THE DRAWINGS

These and other features, aspects, and advantages of the present invention will become apparent from the following description, appended claims, and the accompanying exemplary embodiments shown in the drawings, which are briefly described below.

FIG. 1 is a block diagram of a solar conversion system according to an exemplary embodiment.

FIG. 2 is a schematic cross section of a concentrator for the solar conversion system of FIG. 1 according to an exemplary embodiment.

FIG. 3 is a schematic cross section of a concentrator for the solar conversion system of FIG. 1 according to another exemplary embodiment.

FIG. 4 is a schematic ray trace diagram of the concentrator of FIG. 2 showing the propagation of solar light rays through the concentrator.

FIG. 5 is a schematic ray trace diagram of the concentrator of FIG. 3 showing the propagation of solar light rays through the concentrator.

FIG. 6 is a block diagram of a solar conversion system according to another exemplary embodiment including a system for recovering useful heat from the system.

FIG. 7 is a schematic cross section of a concentrator for the solar conversion system of FIG. 1 according to another exemplary embodiment.

### DETAILED DESCRIPTION

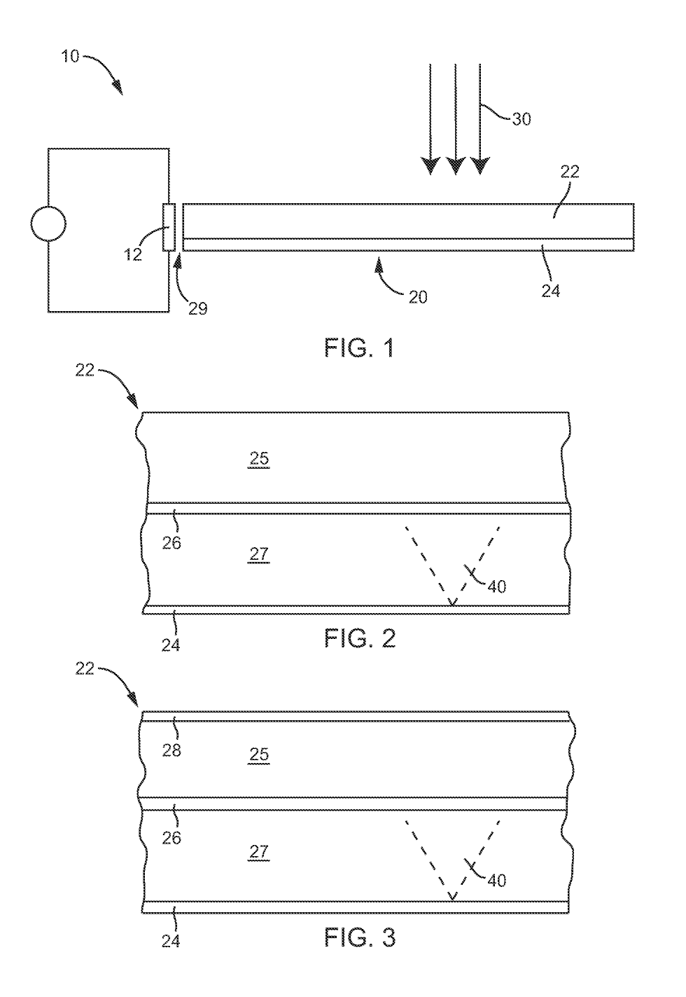

Referring to FIG. 1, a solar energy conversion system 10 (e.g., solar energy conversion apparatus, etc.) is shown according to an exemplary embodiment. The solar conversion system 10 collects solar energy and converts it to another from of energy that is useful to do work using an energy transducer 12. According to an exemplary embodiment, the energy transducer 12 is a photovoltaic cell (e.g. a Si-based solar cell) that is configured to convert the solar energy to an electrical current.

As shown in more detail in FIG. 2, a concentrator 20 is provided to increase the amount of light (as shown, incident solar light) that is directed towards the energy transducer 12, thereby increasing the amount of light energy that may be converted by the energy transducer 12. The concentrator 20 collects solar energy over a fairly large area (e.g., larger than the area of the area of the energy transducer 12) and directs it through an output 29 toward the energy transducer 12. The concentrator 20 includes a material forming a light guide 22 (e.g., light pipe, wave guide, etc.). As described in further detail below, concentrator 20 includes a luminescent material capable of altering (e.g.) the spectrum of light directed to the energy transducer 12.

A reflector 24 is positioned in, on, or near concentrator 20. As described in further detail below, the reflector 20 may be a diffuse reflector which reflects a portion of light exiting the concentrator 20 back in to the concentrator 20. Accordingly, light which would otherwise have been lost is directed back into the collector, thereby improving efficiency.

The light guide 22 forms the main body of the concentrator 20 and is configured to redirect solar energy towards the energy transducer 12. The light guide 22 is an at least partially transparent body with an index of refraction that is greater than that of the surrounding substance (e.g., air). The light guide includes an upper layer 25, an active, luminescent layer 26, and a lower layer 27.

The light guide 22 uses total internal reflection to direct solar energy towards the output 29 of the light guide 22. The refractive index of the material that totals the light guide 22 and refractive index of the surrounding media (e.g. air) determine a critical angle. Light propagating through the light guide 22 that approaches the interface between the light guide 22 and the surrounding media at an angle greater than the critical angle is internally reflected back into the light guide. Light that approaches the interface at an angle less than the critical angle, shown as a wedge-shape area 40 in FIG. 2, is able to escape the light guide 22. In three dimensional space, this area is extrapolated as an “escape cone”, where light travelling in the escape cone is not totally internally reflected and is partially transmitted.

The shape and dimensions of the light guide 22 may vary. The shape of the light guide 22 depends upon the desired application for the solar concentrator. According to one exemplary embodiment, the light guide 22 is a planar strip or sheet or several layers of strips or sheets. The area of such a sheet-like light guide 22 may vary widely depending upon the application. For example, the area of each layer may be relatively small (e.g., about 10 cm² or less), or relatively large (e.g., about 1 m² or more).

In some embodiments, the upper layer 25 and the lower layer 27 are formed of a solid, transparent material, such as glass, quartz crystal, or a polymer, such as a thermoplastic material. Suitable thermoplastic materials include, but are not limited to high molecular weight polymers such as acrylonitrile butadiene styrene (ABS), acrylic, celluloid, cellulose acetate, ethylene-vinyl acetate (EVA), ethylene vinyl alcohol (EVAL), fluoroplastics (PTFEs, including FEP, PFA, CTFE, ECTFE, ETFE), ionomers kydex, a trademarked acrylic/PVC alloy, liquid crystal polymer (LCP), polyacetal (POM or Acetal), polyacrylates (Acrylic), polyacrylonitrile (PAN or Acrylonitrile), polyamide (PA or Nylon), polyamide-imide (PAI), polyaryletherketone (PAEK or Ketone), polybutadiene (PBD), polybutylene (PB), polybutylene terephthalate (PBT), polyethylene terephthalate (PET), Polycyclohexylene Dimethylene Terephthalate (PCT), polycarbonate (PC), polyhydroxyalkanoates (PHAs), polyketone (PK), polyester polyethylene (PE), polyetheretherketone (PEEK), polyetherimide (PEI), polyethersulfone (PES), polysulfone polyethylenechtorinates (PEC), polyimide (PI), polylactic acid (PLA), polymethylpentene (PMP), polyphenylene oxide (PPO), polyphenylene sulfide (PPS), polyphthalamide (PPA), polypropylene (PP), polystyrene (PS), polysulfone (PSU), polyvinyl chloride (PVC), polyvinylidene chloride (PVDC) and spectralon. In some embodiments, the upper layer 25, the lower layer 27, or both include polystyrene. Polystyrene, as well as a number of other thermoplastic materials, is flexible, durable, lightweight, and inexpensive, each of which is a desirable characteristic for a solar concentrator.

The luminescent layer 26 is an active layer sandwiched between the upper layer 25 and the lower layer 27. The luminescent layer 26 absorbs incoming light and re-emits light at a frequency that differs from frequency of the incoming light, and over a range of angles. According to one exemplary embodiment, the luminescent layer 26 red-shifts the light, decreasing the frequency. The luminescent layer absorbs both diffuse and direct solar radiation incident at all angles, and thus requires no tracking. Because the luminescent process red shifts the spectrum, the connection between brightness and entropy allows large concentration ratios to be achieved, even for diffuse light.

Photovoltaic cells (e.g., energy transducer 12) in a circuit generate an electrical current when photons (e.g., in sunlight) with an energy above he band gap strike the photovoltaic cell and create an electron-hole pair. The electron-hole pair is created only if the energy of the photon is higher than the band gap of the photovoltaic cell. However, excess energy above the band gap (e.g., from high energy ultraviolet rays) is converted into heat in the photovoltaic cell. Excess heat decreases the performance and efficiency of the cell. By red-shifting the incoming photons, the luminescent layer 26 reduces the energy of the photons reaching the photovoltaic cell 12 so that they are closer to the band gap of the photovoltaic cell. For example, in embodiments where photovoltaic cell 12 is a Si-based device, luminescent layer 26 may red-shift the spectrum of incident solar radiation such that photons in the UV and visible are red-shifted towards and/or into the near infrared and infrared.

According to an exemplary embodiment, the luminescent layer 26 includes a multitude of quantum dots that are arranged in a single layer housed between the upper layer 25 and the lower layer 27 of the light guide 22. As used herein and as understood by those of skill in the art, “quantum dots” are semiconductors whose excitons are confined in three dimensions to a nano-scale region. Quantum dots may include nanoparticles (e.g. nanocrystals) having a characteristic size in a range of about 1 nm to about 100 nm. Quantum dots have quantum optical properties that are absent in the bulk material due to the confinement of electron-hole pairs excitons on the particle, e.g. in a region of a few nanometers.

In some embodiments, quantum dots have the following optical properties. They are highly absorbent of incident radiation and have very bright emission (fluorescence) under optical excitation. The emission peak of quantum dots may be red-shifted from their absorption spectrum.

In various embodiments, a variety of quantum dots may be used with the disclosed solar concentrators. In some embodiments, the quantum dots include infrared (IR) emitting quantum dots. By “infrared emitting,” it is meant that the quantum dots emit light in the infrared region of the electromagnetic spectrum, i.e., from about 700 nm to about 2500 nm. In some embodiments, the quantum dots include those quantum dots having an emission spectrum that exhibits a maximum between about 750 nm and about 1100 nm. This includes quantum dots exhibiting an emission maximum at about 800 nm, about 850 am, about 900 nm, and about 1000 nm.

However, for various applications suitable quantum dots may include quantum dots that emit light in other regions of the electromagnetic spectrum. In some embodiments, the quantum dots comprise cadmium selenide (CdSe), cadmium sulfide (CdS), indium arsenide (InAs), indium phosphide (InP) or combinations thereof. In other embodiments, the quantum dots comprise zinc selenide (ZnSe), titanium dioxide (TiO2), or combinations thereof. In still other embodiments, the quantum dots do not comprise cadmium selenide.

in other exemplary embodiments, the luminescent layer may be an organic dyes such as rhodamine B; coumarin; a Lumogen dyes, marketed by BASF SE; or Macrolex Fluorescence Red G, marketed by Lanxess AG.

Referring back to FIG. 1, the diffuse reflector layer 24 is disposed on or near the outer surface of the lower layer 27 of the light guide 22. A diffuse reflector may include any surface which reflects light incident at a given angle back over a range of angles. The diffuse reflector layer 24 may be any suitably diffusely reflective material known in the, such as a textured surface with irregularities so large compared to the wavelengths of the incident radiation that the reflected rays are sent back in multiple directions.

In various embodiments, the diffuse reflector 24 may include a highly efficient diffusely reflective surface. For example, the surface may diffusely reflect greater than 75%, greater than 80%, greater than 85%, greater than 90%, greater than 95%, greater than 99%, or more of light incident upon it. In some embodiments, the diffuse reflector may exhibit this high efficiency over a broad range of wavelengths, e.g. over substantially all of the solar spectrum, and or in a range containing light ranging from the LTV or visible to the near infrared or infrared.

The diffuse reflector layer 24 reflects a portion of the light which exits the light guide 22 (e.g. light at angles within the escape cone) back into the light guide 22. A first portion of this reflected light will reenter the concentrator 20 at angles at angles outside of the escape cone to be subsequently internally reflected to output 29. A second portion will reenter the concentrator 20 at angles at angles within the escape cone, and will therefore make a single pass back through the concentrator 20.

The diffuse reflector 24 provides several advantages. First, in the absence of the reflector, frequency shifted light emitted from the luminescent layer 26 within the escape cone would exit the concentrator 20 and be lost before reaching photocell transducer 12. As described in detail below, reflector 24 diffusely reflects at least a portion of this light back into the concentrator 20 and angles outside of the escape cone to be guided to the photocell transducer 12.

Second, in the absence of the reflector, solar light incident on the concentrator at angles within the loss cone (e.g. direct, normally incident rays) will make only a single pass through the luminescent layer of concentrator 20. As described in detail below, reflector 24 diffusely reflects at least a portion of this light back into the concentrator 20 and angles outside of the escape cone to be totally internally reflected within the concentrator 20, thereby making multiple passes through luminescent layer 26.

For some application, the above advantages, combined with the reduced or eliminated need for solar tracking in the devices described herein provide for high efficiency, low cost power generation. In some embodiments, the presence of the diffuser can improve the power generation efficiency of the system 10 by a factor of about 2 or about 3 or more. As is well known in the art, high efficiency is often important or even critical for the commercial viability of energy sources.

To farther improve efficiency, the collector 20 may further include a selective reflector 28 on the outer surface of the upper layer 25 of the light guide 22 (e.g., opposite of the diffuse reflector layer 24) as shown in FIG. 3. The selective reflector 28 is a selectively reflective layer, constructed of any suitable material known in the art, which is substantially transparent to the incident light and selectively reflects the frequency-shifted light. According to an exemplary embodiment, the selective reflector 28 has a transmissivity of at least 0.9 to incident light in a selected wavelength band and a reflectivity of at least 0.9 to Stokes shifted light in a selected wavelength band. According to other exemplary embodiments, the selective reflector has a transmissivity of at least 50% to incident light over the solar spectrum and a reflexivity of at least 90% to the Stokes shifted light.

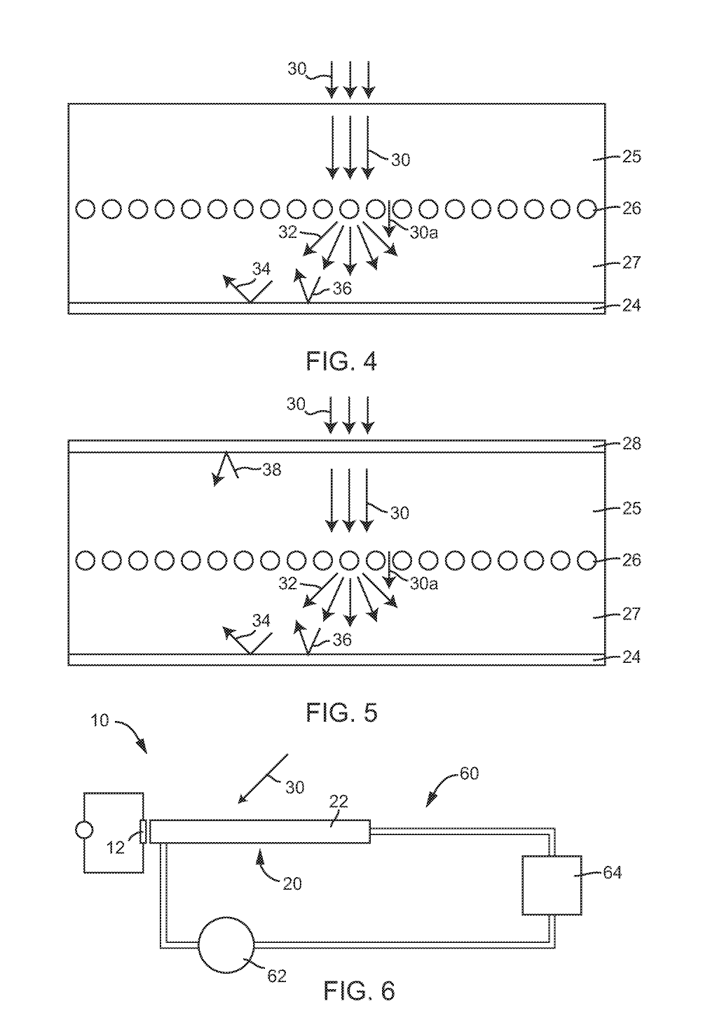

FIG. 4 is a schematic ray trace diagram of the concentrator 20 showing the propagation of solar light rays 30 through the concentrator 20. A first group of rays 30 propagate through the concentrator 20 (e.g., the upper layer 25) and some of the first rays 30 are absorbed by the luminescent layer 26. Some of the first group of rays 30a may not be absorbed by the luminescent layer 26. The first group of rays 30 that are absorbed by the luminescent layer 26 are remitted as a second group of rays 32 that have a wavelength longer than the wavelength of the first group of rays 30. The luminescent layer 26 scatters the light, so the second group of rays 32 (e.g., red-shifted rays) is at a variety of incident angles relative to the first set of rays 30. The scattering occurs if the incoming light 30 is a directed light or a diffuse light.

The luminescent layer 26 scatters the second group of rays 32 such that they propagate through the lower layer 27 towards the back surface of the light guide 22. A third group of rays 34 are reflected from the back surface interface by total internal reflection (TIR). A fourth group of rays 36 propagate through the lower layer 27 at an angle that would normally allow them to escape the light guide 22 (e.g., light in the escape cone determined by the refractive indexes of the material of the lower layer 27 and the surrounding media). However, in the concentrator 20 shown in FIG. 4, the fourth group of rays 36 are reflected back into the light guide 22 by the diffuse reflector 24 that is disposed on or near the outside surface of the lower layer 27. As described above, a portion of the light will be reflected at angles outside of the loss cone, such that this light is guided to transducer 12.

Because not all of the first group of rays 30 are absorbed and red-shifted by the luminescent layer 26 (e.g., light ray 30a), single pass luminescent systems may be constrained to low overall conversion efficiencies because of the low absorption of a single pass solar radiation through the luminescent layer 26. The diffuse reflector layer 24 forms a recycling cavity that gives radiation that is not absorbed by the luminescent layer 26, the radiation escaping via the direct TIR escape cone as well as the radiation escaping via re-absorption radiation escape cone a second chance to be absorbed and red-shifted by the luminescent layer 26, thereby increasing the overall conversion efficiency of the concentrator 20. Increasing the overall efficiency of a passive concentrator 20 allows it to be more competitive with more complex systems that require active or passive one axis or two axis tracking systems.

FIG. 5 is a ray trace diagram of the concentrator 20 according to another exemplary embodiment including a selective reflector 28 that is disposed on the outer surface of the upper layer 25 of the light guide 22 (e.g., opposite of the diffuse reflector layer 24). As described above, the selective reflector 28 is a selectively reflective layer that is substantially transparent to the incident light rays 30. The first rays 30 are therefore able to enter and propagate through the upper layer 25 normally (e.g., as shown and described with regards to FIG. 4).

However, the selective reflector 28 selectively reflects the frequency-shifted light (e.g., second rays 32). Therefore, a frequency-shifted fifth group of rays 38 that would otherwise escape via the TIR escape cone are reflected back into the upper layer 25 of the light guide 22.

The shape and dimensions of the light guide 22 may vary. The shape of the light guide 22 depends upon the desired application for the solar concentrator. According to one exemplary embodiment, the light guide 22 is a planar strip or sheet or several layers of strips or sheets. The area of such a sheet-like light guide 22 may vary widely depending upon the application. For example, the area of each layer may be relatively small (e.g., about 10 cm²), or relatively large (e.g., about 1 m²).

According to another exemplary embodiment, the light guide may be a cylindrical member. The luminescent layer may be a line, plane (e.g. monolayer), or cylindrical group of quantum dots that extends along the longitudinal axis of the light guide. All or a portion of the outside surface of the light guide may include a reflective or selectively reflective coating (e.g., diffuse reflector 24 or selective reflector 28). According to other exemplary embodiments, the light guide may be otherwise shaped, such as a curved plane.

The thickness each layer of the light guide 22 may also vary. In some embodiments, the upper layer 25 and/or the lower layer 27 are sufficiently thick so that the amount of light emitted by the luminescent layer 26 through the top or bottom surface of the solar concentrator 20 is minimized. In some embodiments, the thickness of the lower layer 27 and the upper layer 25 ranges from about 0.25 mm to about 5 mm. According to a preferred embodiment, the thickness of the upper layer 25 and/or the lower layer 27 is between 0.5 mm and 4 mm. According to a particularly preferred embodiment, the thickness of the upper layer 25 and/or the lower layer 27 is between 1 mm and 3 mm.

Referring now to FIG. 6, according to another exemplary embodiment, the solar conversion system 10 includes a thermal conversion system 60 for removing and using excess heat from the concentrator 20. In such an embodiment, the light guide 22 may comprise one or more layers formed as a fluid-filled shell. The shell is a transparent, thin-walled body that is filled with a fluid, such as water that is able to absorb excess heat in the concentrator 20. A circulator 62 (e.g., a pump, etc.) moves the fluid from the light guide through the thermal conversion system 60. The thermal conversion system 60 further includes a device 64 that removes heat from the fluid before it is circulated back to the light guide 22. In this way, excess heat that is generated by the incident light rays is removed from the solar conversion system 10.

According to one exemplary embodiment, the device 64 is a simple heat sink, heat pipe, other device or combination of devices that is configured to dissipate the excess heat, such as into the air. The heat sink or other device may dissipate the heat passively, or may include a fan or other device to increase the heat removed from the fluid.

According to another exemplary embodiment, the device 64 is a heat exchanger. The heat exchanger may be similar to the heat sink and be configured to dissipate the excess heat from the fluid to the air. In other embodiments, the heat exchanger may be coupled to another system, and the excess heat may be transferred from the light guide fluid to another working fluid in the heat exchanger.

According to another exemplary embodiment, the device 64 may be a generator. For example, the fluid may be converted to a vapor in the concentrator 20 (e.g., steam, etc.) and the device 64 may be a turbine that is driven by the vaporized fluid.

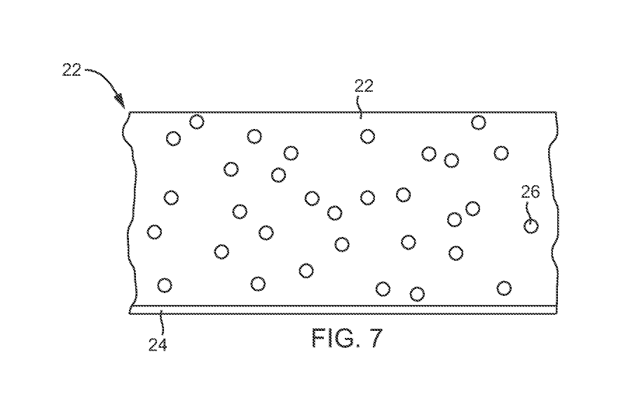

While the luminescent material for the concentrator 20 is described above and shown in FIGS. 2-5 as being provided as an active layer sandwiched between the upper layer 25 and the lower layer 27, in other exemplary embodiments the luminescent material may be arranged differently. Referring to FIG. 7, in another exemplary embodiment, the concentrator 20 may include a luminescent material 26 comprising quantum dots or organic dye molecules that is dispersed throughout the material forming the light guide 22.

As will be understood by one skilled in the art, for any and all purposes, particularly in terms of providing a written description, all ranges disclosed herein also encompass any and all possible subranges and combinations of subranges thereof. Any listed range can be easily recognized as sufficiently describing and enabling the same range being broken down into at least equal halves, thirds, quarters, fifths, tenths, etc. As a non-limiting example, each range discussed herein can be readily broken down into a lower third, middle third and upper third, etc. As will also be understood by one skilled in the art all language such as “up to,” “at least,” “greater than,” “less than,” and the like include the number recited and refer to ranges which can be subsequently broken down into subranges as discussed above.

All publications, patent applications, issued patents, and other documents referred to in this specification are herein incorporated by reference as if each individual publication, patent application, issued patent, or other document were specifically and individually indicated to be incorporated by reference in its entirety. Definitions that are contained in text incorporated by reference are excluded to the extent that they contradict definitions in this disclosure.

For the purposes of this disclosure and unless otherwise specified, “a” or “an” means “one or more.”

As used herein, the term “comprising” is intended to mean that the compositions and methods include the recited elements, but not excluding others. “Consisting essentially of” when used to define compositions and methods, shall mean excluding other elements of any essential significance to the combination for that intended purpose. “Consisting of” shall mean excluding more than trace elements of other ingredients and substantial method steps for making or using the concentrators or articles of this invention.

The construction and arrangements of the solar energy concentrator, as shown in the various exemplary embodiments, are illustrative only. Although only a few embodiments have been described in detail in this disclosure, many modifications are possible (e.g., variations in sizes, dimensions, structures, shapes and proportions of the various elements, values of parameters, mounting arrangements, use of materials, colors, orientations, etc.) without materially departing from the novel teachings and advantages of the subject matter described herein. Some elements shown as integrally formed may be constructed of multiple parts or elements, the position of elements may be reversed or otherwise varied, and the nature or number of discrete elements or positions may be altered or varied. The order or sequence of any process, logical algorithm, or method steps may be varied or re-sequenced according to alternative embodiments. Other substitutions, modifications, changes and omissions may also be made in the design, operating conditions and arrangement of the various exemplary embodiments without departing from the scope of the present disclosure.

What is claimed is:

1. An apparatus comprising;
a wave-guide containing a luminescent material which responds to incident light by emitting frequency-shifted light, wherein
a first portion of the frequency-shifted light is internally reflected within the wave-guide to a wave-guide output, and
a second portion of the frequency-shifted light is transmitted out of the wave-guide; and
a diffuse reflector positioned proximal to the waveguide to reflect at least some of the second portion of the frequency-shifted light back in to the waveguide to be internally reflected within the wave-guide to a wave-guide output.

2. The apparatus of claim 1, further comprising an absorber positioned proximal to the wave-guide to produce energy in response to the frequency-shifted light.

3. The apparatus of claim 2, wherein the absorber comprises a photovoltaic device.

4. The apparatus of claim 1, wherein the diffuse reflector reflects greater than about 90% of the frequency shifted light incident upon it.

5. The apparatus of claim 1, wherein the luminescent material comprises quantum dots or an organic dye.

6. The apparatus of claim 5, wherein the quantum dots comprise particles ranging between about 1 to 10 nanometers in size.

7. The apparatus of claim 5, wherein the quantum dots comprise material selected from the group consisting of lead sulfide (PbS), cadmium selenide (CdSe), cadmium sulfide (CdS), indium arsenide (InAs), and indium phosphide (InP).

8. The apparatus of claim 5, wherein the quantum dots comprise material selected from the group consisting of zinc selenide (ZnSe), and titanium dioxide (TiO2).

9. The apparatus of claim 5, wherein the layer of quantum dots comprises a monolayer of quantum dots.

10. The apparatus of claim 5, wherein the quantum dots are suspended in a polymeric material.

11. The apparatus of claim 1, wherein the waveguide comprises:
an upper layer which is substantially transparent to the incident light;
an active layer comprising the luminescent material, the active layer underlying the upper layer; and
a lower layer underlying the active layer which is substantially transparent to the frequency-shifted light; and
wherein the diffuse reflector comprises a diffusely reflective layer underlying the lower layer.

12. The apparatus of claim 11, further comprising a selectively reflective layer overlying the upper layer which is substantially transparent to the incident light and selectively reflects the frequency-shifted light.

13. The apparatus of claim 12, wherein the incident light is solar light.

14. The apparatus of claim 13, wherein the frequency-shifted light is red shifted relative to the solar light.

15. The apparatus of claim 12, wherein at least portions of the selectively reflective later and the diffusely reflective layer face each other to form a reflective cavity for the frequency-shifted light.

16. The apparatus of claim 1, further comprising a selective reflector located proximal the waveguide which selectively admits the incident light into the waveguide and which selectively reflects frequency-shifted light from the wave-guide back into the waveguide.

17. The apparatus of claim 12, wherein at least portions of the selective reflector and the diffuse reflector face each other to form a reflective cavity for the frequency-shifted light.

18. The apparatus of claim 16, wherein the selective reflector has a transmissivity of at least 0.9 to incident light and a reflectivity of at least 0.9 to the red shifted light.

19. The apparatus of claim 1, wherein the waveguide is flexible.

20. The apparatus of claim 1, wherein the waveguide comprises a fluid filled shell.

21. The apparatus of claim 20, further comprising a circulator which circulates fluid through the fluid filled shell.

22. The apparatus of claim 21, further comprising a heat exchanger configured to remove heat from the fluid.

23. The apparatus of claim 1, further comprising at lease one heat sink configured to remove heat from the waveguide.

24. The apparatus of claim 23, further comprising a generator configured to generate electrical power from the removed heat.

25. The apparatus of claim 1, further comprising a concentrator which concentrates the incident light onto the waveguide.

26. A method of generating electrical power comprising:
obtaining a concentrating apparatus comprising
a wave-guide containing a luminescent material which responds to incident light by emitting frequency-shifted light, wherein
a first portion of the frequency-shifted light is internally reflected within the wave-guide to a wave-guide output, and
a second portion of the frequency-shifted light is transmitted out of the wave-guide; and
a diffuse reflector positioned proximal to the waveguide to reflect at least some of the second portion of the frequency-shifted light back in to the waveguide to be internally reflected within the wave-guide to a wave-guide output;
positioning a photovoltaic device proximal to the wave-guide output;
receiving incident light with the concentrating apparatus to produce frequency-shifted light; and
directing at least a portion of the frequency-shifted light to the photovoltaic device to generate electrical power.

27. The method of claim 26, comprising:
admitting a portion of the incident light into the waveguide through the selective reflective surface and onto the luminescent material;
causing the luminescent material to emit frequency-shifted light in response to the incident light;
using the diffuse reflector to reflect a portion of the frequency-shifted light which exits the waveguide back into the waveguide to be internally reflected within the wave-guide to the wave-guide output.

28. The method of claim 27, wherein the incident light is solar light.

29. The method of claim 28, wherein the frequency-shifted light is red shifted relative to the solar light.

30. The method of claim 29, wherein the luminescent material comprises quantum dots.

31. The method of claim 30, wherein the quantum dots comprise particles ranging between about 2 to 10 nanometers in size.

32. The method of claim 30, wherein the quantum dots comprise material selected from the group consisting of cadmium selenide (CdSe) cadmium sulfide (CdS), indium arsenide (InAs), and indium phosphide (InP).

33. The method of claim 30 wherein the quantum dots comprise material selected from the group consisting of lead sulfide (PbS), zinc selenide (ZnSe), and titanium dioxide (TiO2).

34. The method of claim 26, wherein the concentration apparatus further comprises a selective reflector located proximal the waveguide which selectively admits the incident light into the waveguide and which selectively reflects frequency-shifted light from the wave-guide back into the waveguide; and
further comprising:
admitting a portion of the incident light into the waveguide through the selective reflective surface and onto the luminescent material;
causing the luminescent material to emit frequency-shifted light in response to the incident light;
using the selective reflector to reflect a portion of the frequency-shifted light which exits the waveguide back into the waveguide to be internally reflected within the wave-guide to the wave-guide output.

35. The method of claim 26, wherein the selective reflector is a diffuse reflector.

36. A system comprising:
an apparatus according to any of claim 1;
an energy transducer located proximal to the wave guide output to receive frequency shifted light and convert the light to another form of energy.

37. The system of claim 36, wherein the transducer comprises a photovoltaic cell.

38. The system of claim 37, wherein the photovoltaic cell has a higher quantum efficiency in response to the frequency shifted light than in response to the incident light.

39. The system of claim 38, wherein the photovoltaic cell comprises a silicon based solar cell.

40. An apparatus comprising;
a wave-guide containing a luminescent material which responds to incident light by emitting frequency-shifted light, and
a diffuse reflector positioned proximal to the waveguide to reflect at least some light exiting the waveguide back in to the waveguide to be internally reflected within the wave-guide.

41. The apparatus of claim 40 wherein the at least some light exiting the waveguide comprises frequency-shifted light emitted from the luminescent material.

42. The apparatus of claim 40 wherein the at least some light exiting the waveguide comprises a non-frequency-shifted portion of the incident light.
